(19) United States
(12) Patent Application Publication
(10) Pub. No.: US 2004/0052149 A1
(43) Pub. Date: Mar. 18, 2004

(54) Integrated microcontroller module and method for checking the functionality of an integrated memory of the microcontroller module

(76) Inventors: Thomas Hanuschek, Poing (DE); Volker Penka, Munchen (DE); Marcel Maass, Bavaria (DE); Till Frohnmuller, Muchen (DE); Thierry Canaud, Munchen (DE)

Correspondence Address: LERNER AND GREENGERG, P.A., POST OFFICE BOX 2480, HOLLYWOOD, FL, 33022-2480, US

(21) Appl. No.: 10/616,114

(22) Filed: Jul. 9, 2003

(30) Foreign Application Priority Data
Jul. 9, 2002 (DE) 102 30 949.3

(51) Int. Cl. G11C 8/02

(52) U.S. Cl. 365/232

(57) ABSTRACT

An integrated module contains a microcontroller and a code/data memory, it being possible for an access to the memory and an external data transfer terminal to be controlled by the microcontroller during normal operation. Furthermore, the carrying out of a test sequence for the functional testing of the memory can be controlled by the microcontroller in a test operation. In a method for checking the functionality of the memory, a command sequence on the basis of which the microcontroller controls the carrying out of the test sequence is read into the module externally before the beginning of the test operation. The command sequence is executed on the microcontroller and defect data are stored in a defect data memory under the control of the microcontroller. Therefore, it is possible to carry out a self-test of the memory, but no additional BIST hardware has to be provided for this purpose.

### BACKGROUND OF THE INVENTION

### FIELD OF THE INVENTION

The present invention relates to an integrated microcontroller module and a method for checking the functionality of an integrated memory of the microcontroller module.

Integrated memories, for example in the form of dynamic random access memories (DRAMs) or static random access memories (SRAMs), are generally subjected to extensive functional tests in the fabrication process. The functional tests serve, inter alia, to identify defective memory cells or defective column lines or row lines. As memory size increases, the cost of functional tests take up an ever-greater proportion of the total production costs of the memory. Therefore, in order to lower the test costs, increasingly methods are being developed such as test modes for the compression of data or additional test logic, for example in the form of built-in self-test (BIST) circuitry.

Integrated memories generally have redundant memory cells for repairing defective memory cells, the redundant memory cells usually being combined to form redundant row lines or redundant column lines which can replace regular lines having defective memory cells in address terms. As a result, integrated memories, in particular in the form of DRAMs, can still be fabricated economically in the context of the integration densities achieved nowadays. An integrated memory is tested by an external test device, for example, and a programming of redundant elements is subsequently performed on the basis of a so-called redundancy analysis. In order to be able to carry out a repair of a memory in a targeted manner, it is necessary in corresponding tests or test sequences, for all the defects to be identified and stored together with the associated address in a memory provided for this purpose. To that end, the addresses of the tested memory cells which have been detected as defective are stored in a defect address memory to form a so-called defect table in order to replace the memory cells by defect-free redundant memory cells in a subsequent step on the basis of the stored addresses. On the basis of the defect table, the repair solution specific to each memory can subsequently be calculated and a so-called fail bit map can be produced.

Advancing development in the field of integrated circuits is accompanied by a generally continual increase in the operating frequency at which an integrated circuit is operated. As operating frequencies of integrated circuits increase, it usually becomes more difficult to test the integrated circuits with regard to their functionality. In this case, to obtain a largely meaningful test result, it is important for the integrated circuit to be tested at an operating frequency that it exhibits in normal operation.

Experience shows, however, that it is a comparatively difficult problem to provide test units for more recent integrated circuits which can assess output signals of a tested integrated circuit, tested and operated at a maximum operating frequency, at the required frequency with sufficient accuracy. Often, such test units are not commercially available or are comparatively expensive. Therefore, for cost reasons it is often highly advantageous for earlier configurations of test units that only support comparatively low frequencies to be made usable for more recent chip generations by chip hardware.

With the use of BIST controllers for the self-test of integrated memories it is necessary to provide additional hardware on the memory chip, which generally leads to an enlargement of the required chip area. A functional test by an external test system in which defect data are stored on the basis of the BIST test generally requires a high outlay with regard to the test setup and the tester hardware, thus resulting in an increase in the test costs and hence the fabrication costs of integrated memories.

### SUMMARY OF THE INVENTION

It is accordingly an object of the invention to provide in an integrated microcontroller module and a method for checking the functionality of an integrated memory of the microcontroller module that overcome the above-mentioned disadvantages of the prior art devices and methods of this general type, which enables test costs or additional chip area, caused in particular by chip hardware that is additionally to be provided for a test operation, to be kept as low as possible.

With the foregoing and other objects in view there is provided, in accordance with the invention, an integrated module. The module contains an external access terminal, a memory for storing code and data, and a microcontroller connected to the external access terminal and to the memory. The microcontroller controls an access to the memory and a data transfer through the external access terminal during normal operation. The microcontroller further controls a performance of a test sequence for functional testing the memory in a test operation of the module. A defect data memory is provided for storing defect data under control of the microcontroller, the defect data being generated during the functional testing.

The integrated module according to the invention has, besides an internal memory for storing code and data, a microcontroller to be connected to the external terminal of the module and to the memory. The microcontroller is provided, in particular, for controlling, in a normal operation of the module, an access to the memory and a data transfer via the external terminal of the module. The memory is embodied for example as an SRAM and the microcontroller as a hard disk controller, for example, for using the module in a computer system.

According to the invention, the microcontroller, which is provided anyway for the normal operation in the application, is configured in such a way that, in a test operation of the module, it can control the carrying out of a test sequence for the functional testing of the memory. Also present is a defect data memory for storing defect data under the control of the microcontroller, the defect data being generated during the checking of functionality.

In accordance with a method of the invention for checking the functionality of the memory of an integrated module of this type, a command sequence on the basis of which the microcontroller controls the carrying out of a test sequence is read into the module externally before the beginning of the test operation. The loaded command sequence is executed for carrying out the test sequence by the microcontroller. In this case, defect data are stored in the defect data memory using the microcontroller.

The present invention advantageously makes it possible to dispense with BIST hardware on the module. As a result, valuable chip area can be effectively saved. This is particularly advantageous with regard to modules having a high integration density. The respective defect data can be read out by an external test unit at the end of the functional test and may serve in particular as a basis for constructing a fail bit map. As a result, it is possible to use a comparatively cost-effective test system for the functional test since the data communication between the module and the test system does not have to be effected continuously during the test and, therefore, is not time-critical.

Furthermore, it is advantageously possible, even for a wafer level test, to assess test information or defect information and to physically analyze the module. Moreover, it advantageously becomes possible to flexibly optimize a functional test and the test coverage by the functional test. Moreover, the test can be configured flexibly with regard to test speed and storage of test information. Furthermore, the communication between the memory to be tested and a test system during the functional test can be defined correspondingly with regard to an optimized test flow.

In one embodiment of the integrated module according to the invention, the microcontroller has a command memory for storing the externally supplied command sequence on the basis of which the microcontroller controls the carrying out of the test sequence. In one embodiment of the invention, the command memory is part of the microcontroller and equally, in a further embodiment of the invention, the defect data memory is part of the microcontroller.

In accordance with one embodiment of the method of the invention for checking the functioning of the integrated module, after the reading-in of the command sequence at the beginning of the test operation, a jump is made to a start address in an internal command memory. The command sequence is executed under the control of the microcontroller proceeding from the start address and defect data that are generated are stored in the defect data memory under the control of the microcontroller. The defect data stored in the defect data memory can be read out, under the control of the microcontroller, to outside the module in order to evaluate the functional testing. On the basis of this, it is possible to construct a fail bit map for defect analysis purposes.

Other features which are considered as characteristic for the invention are set forth in the appended claims.

Although the invention is illustrated and described herein as embodied in an integrated microcontroller module and a method for checking the functionality of an integrated memory of the microcontroller module, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of an embodiment of an integrated module according to the invention;

FIG. 2 is a block diagram of a more detailed embodiment of the integrated module according to the invention; and

FIG. 3 is a block flow diagram for carrying out a functional test of a memory in accordance with FIG. 2, illustrating the memory components used.

### DESCRIPTION OF THE PREFERRED EMBODIMENTS

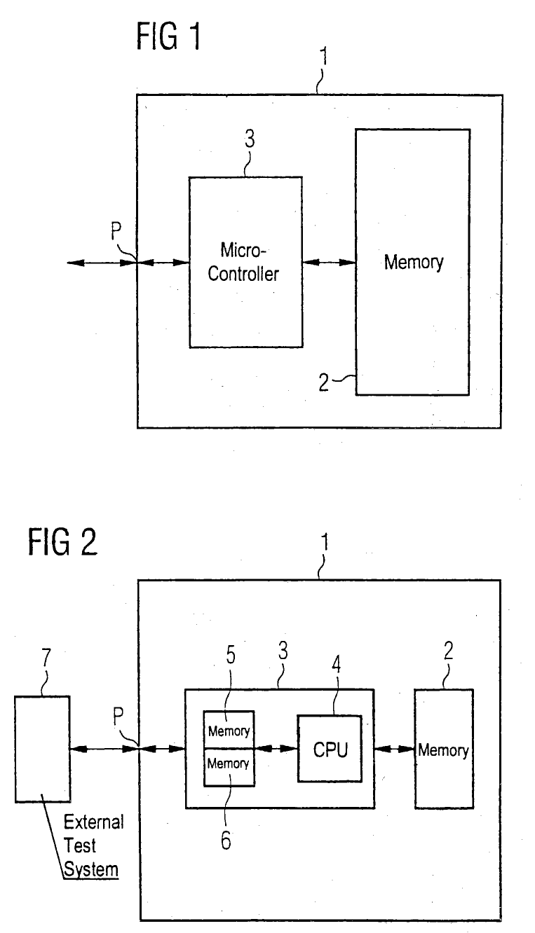

Referring now to the figures of the drawing in detail and first, particularly, to FIG. 1 thereof, there is shown an integrated module 1 having a memory 2 for storing code or data. In the present exemplary embodiment, the memory 2 is embodied as an SRAM or is contained in an SRAM. Furthermore, the module has a microcontroller 3 connected to an external terminal P of the module 1 and to the memory 2. In the normal operation of the module 1, an access to the memory 2 and a data transfer via the external terminal P of the module can be controlled by the microcontroller 3. The microcontroller 3 is embodied as a hard disk controller, for example.

FIG. 2 shows a more detailed embodiment of the integrated module 1 according to the invention. Like the module in accordance with FIG. 1, the module 1 in accordance with FIG. 2 has the memory 2 and the microcontroller 3, which, in a normal operation of the module 1, controls the memory access to the memory 2 and the external data transfer of the module 1.

Parts of the microcontroller 3 include a central processing unit (CPU) 4 and an internal memory, which can be utilized as a command memory 5 and/or as a defect data memory 6. An external test system 7 is connected to the external terminal P. In the present exemplary embodiment, the command memory 5 and defect data memory 6 are part of a so-called dual port RAM.

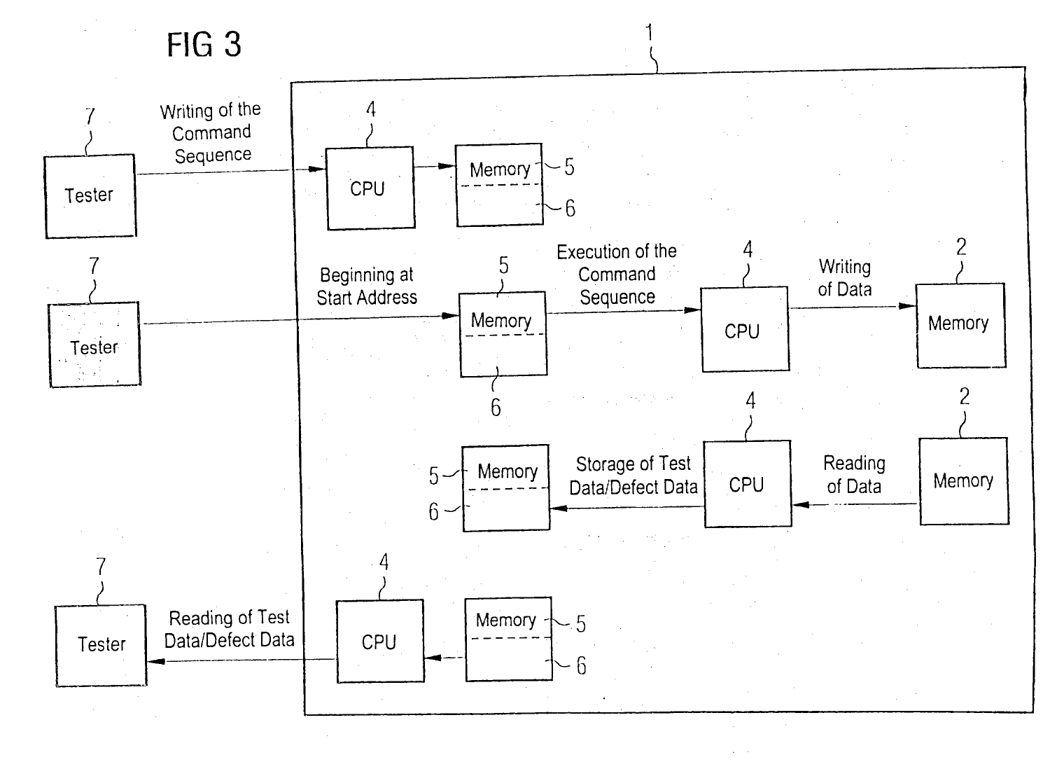

The carrying out of an exemplary functional test will be explained in more detail below with reference to the flow diagram in accordance with FIG. 3.

Before the beginning of the test operation, a command sequence for carrying out a test sequence that is executed on the microcontroller is read in from the test system 7. This process is controlled by the CPU 4, the command sequence being loaded into the command memory 5 (step A). In step B, the test is executed by the CPU 4 from a start address of the internal memory. Accordingly, test data are written to the memory 2 by the CPU 4. In step C, the data are read out again from the memory 2 under the control of the CPU 4 and corresponding defect data are stored in the defect data memory 6 under the control of the CPU 4. Afterward, the defect data stored in the defect data memory 6 are read out to outside the module 1, under the control of the CPU 4, to the test system 7 in order to evaluate the functional testing (step D).

The invention thus makes it possible to carry out a self-test of an integrated memory, but no additional BIST hardware has to be provided for this purpose. The invention advantageously makes it possible first to simulate a functional test of the memory in a trial run on a simulator and thereby to optimize the subsequent functional test of the memory. Accordingly, the functional test can first be checked with regard to its functionality by a simulation, and weak points discovered in the process can be eliminated. Furthermore, it is possible to carry out a simulation with regard to an optimum test coverage and/or a timing verification. A further advantage is that with the prior loading of a command sequence, a functional test, in contrast to a BIST realization, can be flexibly adapted to the individual test requirements. Consequently, it is possible to carry out different functional tests, such as, for example, so-called march tests or checkerboard tests for checking static or dynamic memory defects.

We claim:

1. An integrated module, comprising:
an external access terminal;
a memory for storing code and data;
a microcontroller connected to said external access terminal and to said memory, said microcontroller controlling an access to said memory and a data transfer through said external access terminal during normal operation, said microcontroller controlling a performance of a test sequence for functional testing said memory in a test operation of the module; and
a defect data memory for storing defect data under control of said microcontroller, the defect data being generated during the functional testing.

2. The integrated module according to claim 1, further comprising a command memory for storing an externally supplied command sequence and on a basis of the command sequence said microcontroller controls a carrying out of the test sequence.

3. The integrated module according to claim 1, wherein said defect data memory is part of said microcontroller.

4. The integrated module according to claim 2, wherein said command memory is part of said microcontroller.

5. A method for functionally checking a memory of an integrated module, which comprises the steps of:
reading-in a command sequence externally before beginning a test operation, and on a basis of the command sequence a microcontroller controls a carrying out of a test sequence;
executing the command sequence for carrying out the test sequence by the microcontroller; and
storing defect data in a defect data memory under the control of the microcontroller.

6. The method according to claim 5, which further comprises:
making a jump to a start address in an internal command memory after the command sequence is read-in at the beginning of the test operation;
executing the command sequence under the control of the microcontroller proceeding from the start address; and
storing the defect data generated in the defect data memory under the control of the microcontroller; and
reading-out the defect data stored in the defect data memory, under the control of the microcontroller, to outside the integrated module for further evaluation.
